(19) United States
(12) Patent Application Publication
(10) Pub. No.: US 2010/0108976 A1
(43) Pub. Date: May 6, 2010

(54) ELECTRONIC DEVICES INCLUDING CARBON-BASED FILMS, AND METHODS OF FORMING SUCH DEVICES

(75) Inventors: Wipul Pemsiri Jayasekara, Los Gatos, CA (US); April D. Schricker, Palo Alto, CA (US)

Correspondence Address: DUGAN & DUGAN, PC, 245 Saw Mill River Road, Suite 309, Hawthorne, NY, 10532, US

(73) Assignee: SANDISK 3D LLC, Milpitas, CA (US)

(21) Appl. No.: 12/408,419

(22) Filed: Mar. 20, 2009

Related U.S. Application Data
(60) Provisional application No. 61/109,905, filed on Oct. 30, 2008.

(51) Int. Cl. H01L 47/00; H01L 21/205

(52) U.S. Cl. 257/4; 438/507; 257/E47.001; 257/E47.005; 257/E21.101; 977/742

(57) ABSTRACT

Methods in accordance with this invention form microelectronic structures, such as non-volatile memories, that include carbon layers, such as carbon nanotube (“CNT”) films, in a way that protects the CNT film against damage and short-circuiting. Microelectronic structures, such as non-volatile memories, in accordance with this invention are formed in accordance with such techniques.

### REFERENCE TO RELATED APPLICATIONS

This application claims the benefit of U.S. Provisional Patent Application Ser. No. 61/109,905, filed 30 Oct. 2008, which is incorporated by reference herein in its entirety for all purposes.

### BACKGROUND

This invention relates to microelectronic devices, such as non-volatile memories, and more particularly to a memory cell that includes a carbon-based reversible-resistance switching element compatible with a steering element, and methods of forming the same.

Non-volatile memories formed from reversible resistance-switching elements are known. For example, U.S. patent application Ser. No. 11/968,154, filed Dec. 31, 2007, titled “MEMORY CELL THAT EMPLOYS A SELECTIVELY FABRICATED CARBON NANO-TUBE REVERSIBLE RESISTANCE-SWITCHING ELEMENT AND METHODS OF FORMING THE SAME” (hereinafter “the '154 Application”), which is hereby incorporated by reference herein in its entirety for all purposes, describes a rewriteable non-volatile memory cell that includes a diode coupled in series with a carbon-based reversible resistivity-switching material such as carbon.

However, fabricating memory devices from rewriteable resistivity-switching materials is technically challenging, and improved methods of forming memory devices that employ resistivity-switching materials are desirable.

### SUMMARY

This invention pertains to methods for fabricating microelectronic structures, such as metal-insulator-metal (“MIM”) structures, that include CNT films, such as non-volatile memories, to protect an active CNT film against damage and short-circuiting. This invention also pertains to CNT microelectronic structures, such as non-volatile memories, fabricated in accordance with such techniques. In such methods and structures, CNT material may serve as an active switchable insulating layer between a bottom electrode and a top electrode of a MIM. The CNT material may include, for example, a homogeneous CNT film or a heterogeneous mixture of CNT material with pore filler material.

In a first exemplary method in accordance with this invention, an additional carbon-based layer is deposited on top of the active CNT material to act as a protective liner against infiltration of a top electrode material.

In one exemplary aspect in accordance with the first exemplary method of the invention, a method of forming a microelectronic structure is provided, wherein the method includes forming a CNT film above a bottom electrode, forming a carbon-based liner above and in contact with the CNT film, and forming a top electrode above and in contact with the carbon-based liner.

In a second exemplary aspect in accordance with the first exemplary method of the invention, a microelectronic structure is provided that includes a bottom electrode, a CNT film above the bottom electrode, a carbon-based liner above and in contact with the CNT film, and a top electrode above and in contact with the carbon-based liner.

In a second exemplary method in accordance with this invention, the top electrode is deposited using relatively lower energy deposition techniques to reduce damage to and/or infiltration of the CNT material during top electrode deposition. A lower energy deposition technique is one involving energy levels lower than those used in PVD of similar materials. Such exemplary deposition techniques may include, for instance, chemical vapor deposition (“CVD”), atomic layer deposition (“ALD”), a combination of CVD and ALD, and electron beam (“e-beam”) evaporation, and other similar techniques.

In one exemplary aspect in accordance with the second exemplary method of the invention, a method of forming a microelectronic structure is provided, wherein the method includes forming a carbon film above a bottom electrode, the carbon film including active CNT material, and forming a top electrode above and in contact with the carbon film, wherein the top electrode is deposited using a lower energy deposition technique, such as CVD, ALD, e-beam evaporation, or a combination of such techniques.

In a second exemplary aspect in accordance with the second exemplary method of the invention, a microelectronic structure is provided that includes a bottom electrode, a carbon film above the bottom electrode, the carbon film including active CNT material, and a top electrode above and in contact with the carbon film, wherein the top electrode is deposited using a lower energy deposition technique, such as CVD, ALD, e-beam evaporation, or a combination of such techniques. The carbon film may comprise undamaged, or reduced-damage, CNT material that is not penetrated, and preferably not infiltrated, by the top electrode.

In additional exemplary aspects in accordance with the first or second exemplary method of the invention, a microelectronic structure, and a method of forming it, are provided that further include a dielectric sidewall liner and/or a steering element. The steering element may include, for instance, a diode in electrical series with the MIM structure formed by the bottom electrode, carbon-based film, and the top electrode. The sidewall liner may include a silicon nitride film deposited prior to deposition of gap fill material around the MIM structure.

Other features and aspects of this invention will become more fully apparent from the following detailed description, the appended claims and the accompanying drawings.

### BRIEF DESCRIPTION OF THE DRAWINGS

Features of the present invention can be more clearly understood from the following detailed description considered in conjunction with the following drawings, in which the same reference numerals denote the same elements throughout, and in which:

FIG. 1 depicts a cross-sectional, elevational schematic diagram of an exemplary memory cell in accordance with an embodiment of the present invention, the memory cell comprising a metal-insulator-metal structure.

FIG. 2 includes FIGS. 2A and 2B, which depict elevational cross-sections of other exemplary memory cells in accordance with embodiments of the present invention, each memory cell comprising a metal-insulator-metal structure in series with a diode.

FIG. 3 includes FIGS. 3A and 3B, which depict elevational cross-sections of further exemplary memory cells in accordance with further embodiments of the present invention, each memory cell comprising a fill liner surrounding a metal-insulator-metal structure in series with a diode.

FIG. 4 is a perspective view of an exemplary memory level of a monolithic three dimensional memory array provided in accordance with the present invention.

### DETAILED DESCRIPTION

Carbon nanotube (“CNT”) films exhibit resistivity switching behavior that may be used to form microelectronic non-volatile memories. CNT materials have demonstrated memory switching properties on lab-scale devices with a 100× separation between ON and OFF states and mid-to-high range resistance changes. Such a separation between ON and OFF states renders CNT materials viable candidates for memory cells formed using the CNT materials in series with vertical diodes, thin film transistors or other steering elements.

In the aforementioned example, a metal-insulator-metal (“MIM”) stack formed from a CNT material sandwiched between two metal or otherwise conducting layers may serve as a resistance change material for a memory cell. Moreover, a CNT MIM stack may be integrated in series with a diode or transistor to create a read-writable memory device as described, for example, in the '154 Application.

Among the various challenges that integration of CNT material presents is that of etching CNT material, due to the topography of CNT material. For instance, deposited or grown CNT material typically has a rough surface topography, with pronounced thickness variations and porosity resulting in local peaks and valleys. These thickness variations make CNT materials difficult to etch, increasing fabrication costs and complexity associated with their use in integrated circuits. As such, some detail will be provided about the etching processes, but many other process parameters are covered in less detail to avoid obscuring the focus of the invention.

Homogeneous carbon nanotube films are known to be porous, so a conventionally-formed CNT-based MIM structure is prone to short-circuiting. In particular, to form a CNT memory circuit using conventional semiconductor processes, physical vapor deposition (“PVD”) processing steps are typically used to form the top and bottom electrodes of the memory cell. The high energy levels of PVD-based top electrode metal deposition, however, may cause metal to infiltrate, and possibly penetrate, one or more CNT film pores, possibly causing a short with the bottom electrode. Additionally, in both the case of a homogenous CNT film and a heterogeneous CNT film with filler material, the high energy levels used during PVD of metal may cause damage to the active switching CNT material during the top electrode deposition. Embodiments of the present invention seek to avoid such deleterious effects by limiting the exposure of the active CNT material to such high energy levels associated with PVD of top electrode metals.

In accordance with various exemplary embodiments of the present invention, methods and apparatus may involve a microelectronic structure, such as a memory device, having an additional carbon-based layer on top of active CNT material to act as a protective liner against infiltration of a top electrode material. In some embodiments, the additional carbon-based top layer penetrates and/or seals many of the topside pores of the CNT film, impeding penetration of the top electrode metal into the sealed pores. In some embodiments, the carbon-based liner also reduces and/or prevents damage to the CNT material during top electrode deposition by shielding the CNT material from exposure to the metal deposition process.

In accordance with alternative exemplary embodiments of the present invention, methods and apparatus may involve a microelectronic structure, such as a memory device, having a top electrode deposited on top of active CNT material using a deposition technique, such as CVD, ALD, e-beam evaporation, or a combination of such techniques, that have lower energy levels than conventional PVD techniques. In some embodiments, use of such relatively lower energy deposition techniques (compared to conventional PVD techniques) reduces and/or prevents infiltration of a top electrode material into the CNT material. In addition, use of the previously mentioned deposition techniques reduces and/or prevents damage to the CNT material during top electrode deposition in some embodiments.

In accordance with additional exemplary embodiments of the present invention, methods and apparatus may involve a microelectronic structure, such as a memory device, having a CNT MIM stack formed using a lower energy deposition technique to deposit the top electrode, and the MIM may be integrated in series with a diode or transistor to create a read-writable memory device.

In accordance with further exemplary embodiments of the present invention, methods and apparatus may involve a microelectronic structure, such as a memory device, having a CNT MIM stack formed using a lower energy deposition technique to deposit the top electrode on a carbon-based layer, and the MIM may include a dielectric sidewall liner that protects the carbon-based layer against deterioration possible during deposition of dielectric gap fill material.

In exemplary embodiments in accordance with this invention, the CNT material may be composed of, but is not limited to, pure carbon nanotubes deposited by CVD growth techniques, colloidal spray on techniques, and spin on techniques. The active switching carbon layer can also be composed of a mixture of amorphous carbon or other dielectric filler material with carbon nanotubes in any ratio deposited in any of the above mentioned techniques. A preferred embodiment of this integration scheme includes a spin or spray application of the CNT material, followed by deposition of amorphous carbon from an Applied Materials, Inc., Producer™ tool for use as carbon-based liner material.

As used herein, “CNT” is a short reference to the carbon-based resistivity switching material forming the active layer, although the carbon material is not limited to carbon nanotubes. As used herein, the CNT material also may include carbon in many forms, including graphene, graphite and amorphous carbon. The nature of the carbon-based layer may be characterized by its ratio of forms of carbon-carbon bonding. Carbon typically bonds to carbon to form either an sp²-bond (a trigonal double C═C bond) or an sp³-bond (a tetrahedral single C—C bond). In each case, a ratio of sp²-bonds to sp³-bonds can be determined via Raman spectroscopy by evaluating the D and G bands. In some embodiments, the range of materials may include those having a ratio such as M_{y}N_{z} where M is the sp³ material and N is the sp² material and y and z are any fractional value from zero to 1 as long as y+z=1.

Additionally, CNT material deposition methods may include, but are not limited to, sputter deposition from a target, plasma-enhanced chemical vapor deposition (“PECVD”), PVD, CVD, arc discharge techniques, and laser ablation. Deposition temperatures may range from about 300° C. to 900° C. A precursor gas source may include, but is not limited to, hexane, cyclo-hexane, acetylene, single and double short chain hydrocarbons (e.g., methane), various benzene based hydrocarbons, polycyclic aromatics, short chain ester, ethers, alcohols, or a combination thereof. In some cases, a “cracking” surface may be used to promote growth at reduced temperatures (e.g., about 1-100 angstroms of iron (“Fe”), nickel (“Ni”), cobalt (“Co”) or the like, although other thicknesses may be used).

In some embodiments, the CNT material layer may be the active switching layer. In such cases, even if methods described, like PECVD, are used to form the CNT material, the CNT material type must switch. The CNT material may be deposited in any thickness. In some embodiments, the CNT material may be between about 1-1000 angstroms, although other thicknesses may be used.

Lower energy deposition techniques may be used to form a top electrode with minimal energy imparted to the underlying material, thereby reducing the potential for damage to the carbon memory layer. More specifically, a lower energy deposition technique exposes a deposition surface to less energy than physical vapor deposition does. The energy level of a lower energy deposition technique preferably is insufficient to damage the layer of carbon-based material and thereby render it non-functional. Likewise, the energy level preferably is insufficient to cause the top electrode to infiltrate into and/or penetrate through the layer of carbon-based material.

Lower energy deposition techniques for deposition of the top electrode may include, for instance, CVD, PECVD, thermal CVD, ALD or e-beam evaporation. The ALD method also may include plasma enhanced ALD (“PE-ALD”), “high-throughput” ALD, and any hybridization of ALD and CVD. Materials appropriate for deposition using CVD, PECVD and ALD include, but are not limited to, Si, W, Ti, Ta, WN, TiN, TaN, TiCN, TaCN. Materials appropriate for deposition using thermal CVD include, but are not limited to, doped polysilicon, W and WN. Film layers appropriate for deposition using e-beam evaporation may include W, Ti, Ta or mixed targets thereof.

Although using lower energy levels, these techniques may be done at temperatures higher than those of PVD in the prior art. However, the CNT is expected to be resilient up to these temperatures. The carbon nanotubes are typically formed between 600° C. to 900° C., whereas the doped silicon and tungsten CVD depositions occur at 550° C. and 300° C. to 500° C. respectively. Additionally, typical metal ALD occurs at around 300° C. to 550° C., which is still below the growth temperature of the CNT material. The amorphous filler material that is sometimes used in these films has been annealed at a high temperature, as well in a vacuum environment, and shows no continuous degassing after the initial solvent media is removed. The CNT-based film has been shown to still switch after high temperature processing up to 750° C.

The carbon-based protective liner can be deposited using a similar or different deposition technique than used to deposit the CNT material. Similarly, carbon-based protective liner deposition methods may include, but are not limited to, sputter deposition from a target, PECVD, PVD, CVD, arc discharge techniques, and laser ablation. Deposition temperatures may range from about 300° C. to 900° C. A precursor gas source may include, but is not limited to, hexane, cyclo-hexane, acetylene, single and double short chain hydrocarbons (e.g., methane), various benzene based hydrocarbons, polycyclic aromatics, short chain ester, ethers, alcohols, or a combination thereof.

Moreover, the carbon-based liner may switch, but this is not a necessary feature, and this may not be desired in some embodiments. The carbon-based liner may be deposited in any thickness. In some embodiments, the carbon-based liner may be between about 1-1000 angstroms, although other thicknesses may be used.

The carbon-based liner materials may include carbon in many forms including graphene, graphite and amorphous carbon. The carbon-based liner material preferably may infiltrate pores in the surface of the CNT material, while not forming significant pores of its own. In each case, a ratio of sp² (trigonal double C═C bonds) to sp³ (tetrahedral single C—C bonds) can be determined via Raman spectroscopy by evaluating the D and G bands. In some embodiments, the range of materials may include those having a ratio such as M_{y}N_{z} where M is the sp³ material and N is the sp² material and y and z are any fractional value from zero to 1 as long as y+z=1.

### Exemplary Embodiments

In accordance with a first exemplary embodiment of this invention, formation of a microelectronic structure includes formation of an MIM device having a carbon film disposed between a bottom electrode and a top electrode, the carbon film comprising a CNT layer covered by a carbon-based protective layer. Inasmuch as the top electrode is deposited using a lower energy deposition technique, the carbon film may comprise undamaged, or reduced-damage, CNT material that is not penetrated, and preferably not infiltrated, by the top electrode.

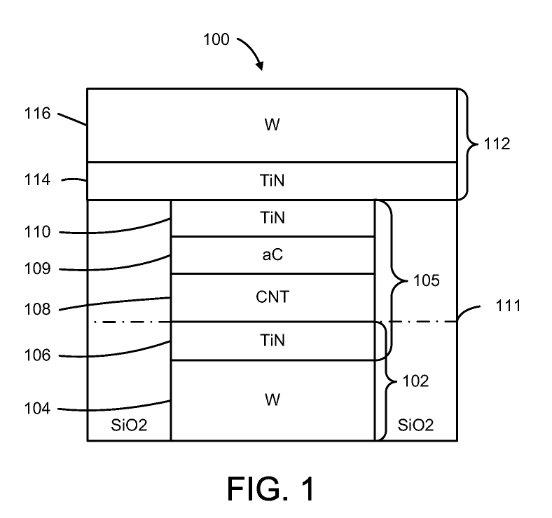

FIG. 1 is a cross-sectional elevational view of a first exemplary microelectronic structure 100, also referred to as memory cell 100, provided in accordance with this invention. Memory cell 100 includes a first conductor 102 formed over a substrate (not shown), such as over an insulating layer over the substrate. The first conductor 102 may include a first metal layer 104, such as a tungsten (“W”), copper (“Cu”), aluminum (“Al”), gold (“Au”), or other metal layer. The first conductor 102 may comprise a lower portion of a MIM structure 105 and function as a bottom electrode of MIM 105. An adhesion layer 106, such as a titanium nitride (“TiN”), tantalum nitride (“TaN”) or similar layer, is optional but is shown in FIG. 1 formed over the first metal layer 104. In general, a plurality of the first conductors 102 may be provided and isolated from one another (e.g., by employing silicon dioxide (“SiO₂”) or other dielectric material isolation between each of the first conductors 102). For instance, the first conductor 102 may be a word-line or a bit-line of grid-patterned array.

A layer of CNT material 108 is formed over the first conductor 102 using any suitable CNT formation process. The carbon-based material 108 may comprise a middle portion of the MIM structure 105, and function as an insulating layer of MIM 105. The CNT material 108 may be deposited by various techniques. One technique involves spray- or spin-coating a carbon nanotube suspension over the first conductor 102, thereby creating a random CNT material. Another technique involves growing carbon nanotubes from a seed anchored to the substrate by CVD, PECVD or the like. Discussions of various CNT deposition techniques are found in the '154 application, and related U.S. patent application Ser. Nos. 11/968,156, “MEMORY CELL THAT EMPLOYS A SELECTIVELY FABRICATED CARBON NANO-TUBE REVERSIBLE RESISTANCE-SWITCHING ELEMENT FORMED OVER A BOTTOM CONDUCTOR AND METHODS OF FORMING THE SAME,” filed Dec. 31, 2007, and 11/968,159, “MEMORY CELL WITH PLANARIZED CARBON NANOTUBE LAYER AND METHODS OF FORMING THE SAME,” filed Dec. 31, 2007, which are hereby incorporated by reference herein in their entireties for all purposes.

In some embodiments in accordance with this invention, following deposition/formation of the CNT material 108, an anneal step may be performed to modify the properties of the CNT material 108. In particular, the anneal may be performed in a vacuum or the presence of one or more forming gases, at a temperature in the range from about 350° C. to about 900° C., for about 30 to about 180 minutes. The anneal preferably is performed in about an 80% (N₂):20% (H₂) mixture of forming gases, at about 625° C. for about one hour.

This anneal may be performed prior to the formation of a top electrode above the CNT material 108. A queue time of preferably about 2 hours between the anneal and the electrode metal deposition preferably accompanies the use of the anneal. A ramp up duration may range from about 0.2 hours to about 1.2 hours and preferably is between about 0.5 hours and 0.8 hours. Similarly, a ramp down duration also may range from about 0.2 hours to about 1.2 hours and preferably is between about 0.5 hours and 0.8 hours.

While not wanting to be bound by any particular theory, it is believed that the CNT material may absorb water from the air and/or might have one or more functional groups attached to the CNT material after the CNT material is formed. Organic functional groups are sometimes required for pre-deposition processing. One of the preferred functional groups is a carboxylic group. Likewise, it is believed that the moisture and/or organic functional groups may increase the likelihood of delamination of the CNT material. In addition, it is believed that the functional groups may attach to the CNT material, for instance, during a cleaning and/or filtering process. The post-carbon-formation anneal may remove the moisture and/or carboxylic or other functional groups associated with the CNT material. As a result, in some embodiments, delamination of the CNT material and/or top electrode material from a substrate is less likely to occur if the CNT material is annealed prior to formation of the top electrode over the CNT material.

Incorporation of such a post-CNT-formation-anneal preferably takes into account other layers present on the device that includes the CNT material, inasmuch as these other layers will also be subject to the anneal. For example, the anneal may be omitted or its parameters may be adjusted where the aforementioned preferred anneal parameters would damage the other layers. The anneal parameters may be adjusted within ranges that result in the removal of moisture and/or carboxylic or other functional groups without damaging the layers of the annealed device. For instance, the temperature may be adjusted to stay within an overall thermal budget of a device being formed. Likewise, any suitable forming gases, temperatures and/or durations may be used that are appropriate for a particular device. In general, such an anneal may be used with any c-based layer or carbon-containing material, such as layers having CNT material, graphite, graphene, amorphous carbon, etc.

Suitable forming gases may include one or more of N₂, Ar, and H₂, whereas preferred forming gases may include a mixture having above about 75% N₂ or Ar and below about 25% H₂. Alternatively, a vacuum may be used. Suitable temperatures may range from about 350° C. to about 900° C., whereas preferred temperatures may range from about 585° C. to about 675° C. Suitable durations may range from about 0.5 hour to about 3 hours, whereas preferred durations may range from about 1 hour to about 1.5 hours. Suitable pressures may range from about 1 mT to about 760 T, whereas preferred pressures may range from about 300 mT to about 600 mT.

In some embodiments in accordance with this invention, following deposition/formation of the CNT material 108, a second carbon-based material layer 109 may be formed as a protective liner covering the CNT material 108. The carbon-based layer 109 serves as a defensive interface with layers above it, in particular the top electrode layers. The carbon-based layer 109 preferably may include amorphous carbon, but other non-CNT carbon-based materials, such as graphene, graphite, diamond-like carbon, or other variations of sp²-rich or sp³-rich carbon materials. The carbon-based material 109 preferably may be adapted to fill pores in the CNT material 108, and not be overly porous itself.

The carbon-based material 109 and its thickness also may be selected to exhibit vertical electrical resistance appropriate for memory cell 100 in which it is incorporated, taking into account, for example, preferred read, write, and programming voltages or currents. Vertical resistance, e.g., in the direction of current travel between the two electrodes as shown in FIG. 1, of the layers 108 and 109 will determine current or voltage differences during operation of structure 100. Vertical resistance depends, for instance, on material vertical resistivity and thickness, and feature size and critical dimension. In the case of CNT material 108, vertical resistance may differ from horizontal resistance, depending on the orientation of the carbon nanotubes themselves, as they appear to be more conductive along the tubes than between the tubes.

After formation of the carbon-based material 109, an adhesion/barrier layer 110, such as TiN, TaN, W, tantalum carbon nitride (“TaCN”), or the like, may be formed over the CNT material 108. As shown in FIG. 1, adhesion layer 110 may function as a top electrode of MIM device 105 that includes CNT material 108 and optional carbon-based material 109 as the insulating layer, and first metal layer 104 and optional adhesion layer 106 as the bottom electrode. As such, the following sections refer to adhesion/barrier layer 110 as “top electrode 110” of MIM 105.

In some embodiments in accordance with this invention, top electrode 110 may be deposited using a lower energy deposition technique, e.g., one involving energy levels lower than those used in PVD of similar materials. Such exemplary deposition techniques may include chemical vapor deposition (“CVD”), plasma enhanced CVD, thermal CVD, atomic layer deposition (“ALD”), plasma enhanced ALD, a combination of CVD and ALD, and electron beam (“e-beam”) evaporation, and other similar techniques.

Use of a lower energy deposition technique to deposit top electrode 110 on the carbon material reduces the potential for deposition-associated damage to the CNT layer 108 and the potential for infiltration and/or penetration of CNT layer 108 by the top electrode 110. In embodiments foregoing the use of a carbon liner 109, use of lower energy deposition techniques may be particularly advantageous to limit the deleterious effects of the deposition of the top electrode 110. Subsequent to the lower energy deposition of top electrode 110, the CNT layer 108 preferably remains undamaged and substantially free of top electrode 110 material, which otherwise might have infiltrated the CNT layer 108 under higher-energy, PVD-type conditions.

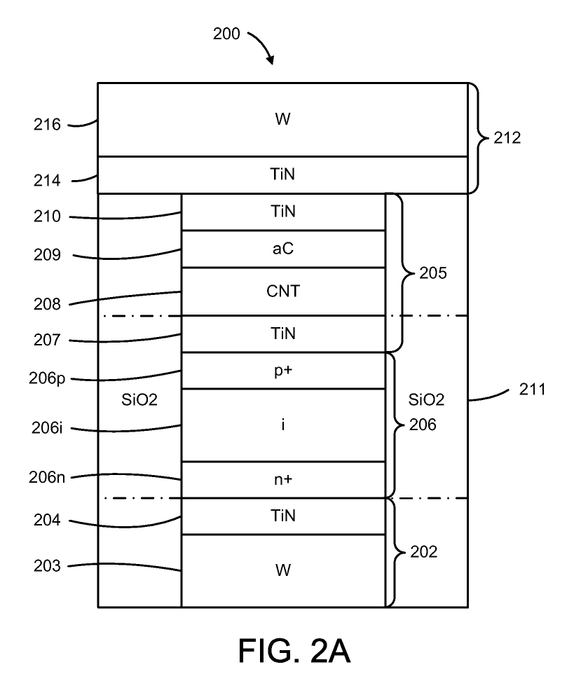

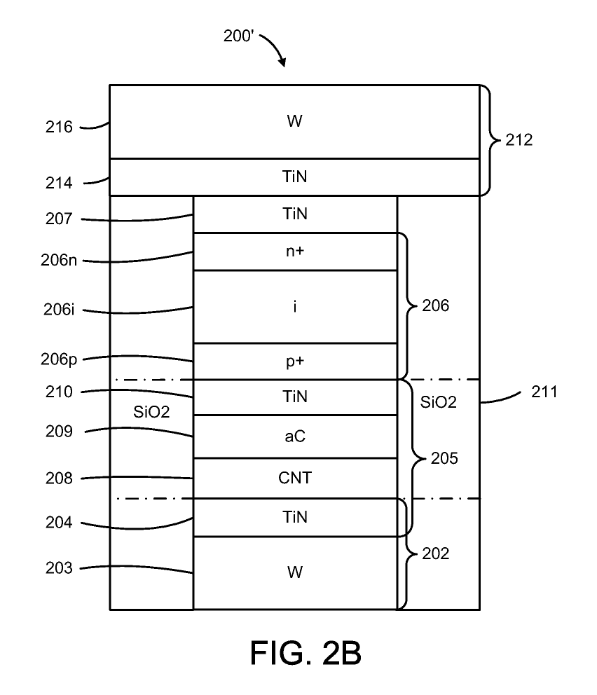

Even if the carbon material (e.g., layers 108 and 109) experiences some damage or infiltration at a top portion (e.g., liner layer 109) serving as an interface with the top electrode 110, at least a core portion of the carbon material (e.g., CNT layer 108) remains functional as a switching element, being undamaged and not infiltrated. The top electrode 110 preferably forms an interface having a sharp profile delimiting the top electrode material and the carbon material. In the event that no carbon liner 109 is present, the possibly-compromised top portion and functioning core may be subdivisions of CNT layer 108. This result preferably applies to the embodiments FIGS. 2-4 as well.

The stack may be patterned, for example, with about 1 to about 1.5 micron, more preferably about 1.2 to about 1.4 micron, of photoresist using standard photolithographic techniques. The top electrode 110 then may be etched using boron trichloride (“BCl₃”) and chlorine (“Cl₂”) chemistries, for example, as described below, or any other suitable etch. In some embodiments, the top electrode 110, the carbon-based liner 109, and the CNT material 108 may be patterned using a single etch step. In other embodiments, separate etch steps may be used.

The CNT materials may be etched using, for example, BCl₃ and Cl₂. Such a method is compatible with standard semiconductor tooling. For example, a plasma etch tool may generate a plasma based on BCl₃ and Cl₂ gas flow inputs, generating reactive species such as Cl+ that may etch a CNT material. In some embodiments, a low bias power of about 100 Watts or less may be employed, although other power ranges may be used. Exemplary processing conditions for a CNT material, plasma etch process are provided below in Table 1. Other flow rates, chamber pressures, power levels, process temperatures, and/or etch rates may be used.

TABLE 1
EXEMPLARY PLASMA ETCH PROCESS PARAMETERS

| | EXEMPLARY | PREFERRED |
|---|---|---|
| PROCESS PARAMETER | RANGE | RANGE |
| BCl₃ Flow Rate (sccm) | 30-70 | 45-60 |
| Cl₂ Flow Rate (sccm) | 0-50 | 15-25 |
| Pressure (milliTorr) | 50-150 | 80-100 |
| Substrate Bias RF (Watts) | 50-150 | 85-110 |
| Plasma RF (Watts) | 350-550 | 390-410 |
| Process Temperature (° C.) | 45-75 | 60-70 |
| Etch Rate (Å/sec) | 3-10 | 4-5 |

Such an etched film stack has been observed to have nearly vertical sidewalls and little or no undercut of the CNT material 108. Other etch chemistries may be used.

The defined top electrode/aC/CNT features may be isolated with SiO₂ or other dielectric fill 111, and then planarized. A second conductor 112 may be formed over the top electrode 110. The second conductor 112 may include a barrier/adhesion layer 114, such as TiN, TaN or a similar material, and a metal layer 116 (e.g., tungsten or other conductive material).

The MIM device 105 may serve as a state change material for memory cell 100. The carbon layers 108 and 109 may form a switchable memory element of the memory cell, wherein the memory element is adapted to switch two or more resistivity states. For example, the MIM device 105 may be coupled in series with a steering element such as a diode, a tunnel junction, or a thin film transistor (“TFT”). In at least one embodiment, the steering element may include a polycrystalline vertical diode.

Memory operation is based on a bi-stable resistance change in the CNT stackable layer 108 with the application of high bias voltage (e.g., >4 V). Current through the memory cell is modulated by the resistance of the CNT material 108. The memory cell is read at a lower voltage that will not change the resistance of the CNT material 108. In some embodiments, the difference in resistivities between the two states may be over 100×. The memory cell may be changed from a “0” to a “1,” for example, with the application of high forward bias on the steering element (e.g., a diode). The memory cell may be changed back from a “1” to a “0” with the application of a high forward bias. As stated, this integration scheme can be extended to include CNT materials in series with a TFT as the steering element instead of a vertical pillar diode. The TFT steering element may be either planar or vertical.

In accordance with a second embodiment of this invention, formation of a microelectronic structure includes formation of a diode in series with an MIM device having a carbon film disposed between a bottom electrode and a top electrode. The carbon film may comprise a CNT layer covered by a carbon-based protective layer, the top electrode may be deposited using a lower energy deposition technique, and the carbon film may comprise undamaged, or reduced-damage, CNT material that is not penetrated, and preferably not infiltrated, by the top electrode.

FIG. 2 is a cross-sectional elevational view of an exemplary memory cell structure 200 provided in accordance with the present invention. FIG. 2 comprises FIGS. 2A and 2B, which depict layers of the memory cell formed in different orders. In FIG. 2A, memory cell structure 200 includes a diode disposed below an MIM device having a CNT film covered by a carbon-based protective layer and disposed between a bottom electrode and a top electrode. In FIG. 2B, memory cell structure 200′ has the diode disposed above the MIM device.

As shown in FIG. 2A, the memory cell structure 200 includes a first conductor 202 formed over a substrate (not shown), such as over an insulating layer covering the substrate. The first conductor 202 may include a first metal layer 203, such as a W, Cu, Al, Au, or other metal layer, with a first barrier/adhesion layer 204, such as a TiN, TaN or similar layer, formed over the first metal layer 203. As shown in FIG. 2B, the first barrier/adhesion layer 204 may comprise a lower portion of a MIM structure 205 and function as a bottom electrode of MIM 205.

In general, a plurality of the first conductors 202 may be provided and isolated from one another. For instance, after patterning and etching first conductors 202, a gap fill deposition of SiO₂ or other dielectric material may isolate each of the first conductors 202. After depositing dielectric material over the first conductors 202, the device structure may be planarized to re-expose the electrically-isolated first conductors 202.

A vertical P-I-N (or N-I-P) diode 206 may be formed above the first conductor 202. For example, the diode 206 may include a polycrystalline (e.g., polysilicon, polygermanium, silicon-germanium alloy, etc.) diode. Diode 206 may include a layer 206n of semiconductor material heavily doped a dopant of a first-type, e.g., n-type; a layer 206i of intrinsic or lightly doped semiconductor material; and a layer 206p of semiconductor material heavily doped a dopant of a second-type, e.g., p-type. Alternatively, as shown in FIG. 2B, the vertical order of the diode 206 layers 206n, 206i, and 206p may be reversed.

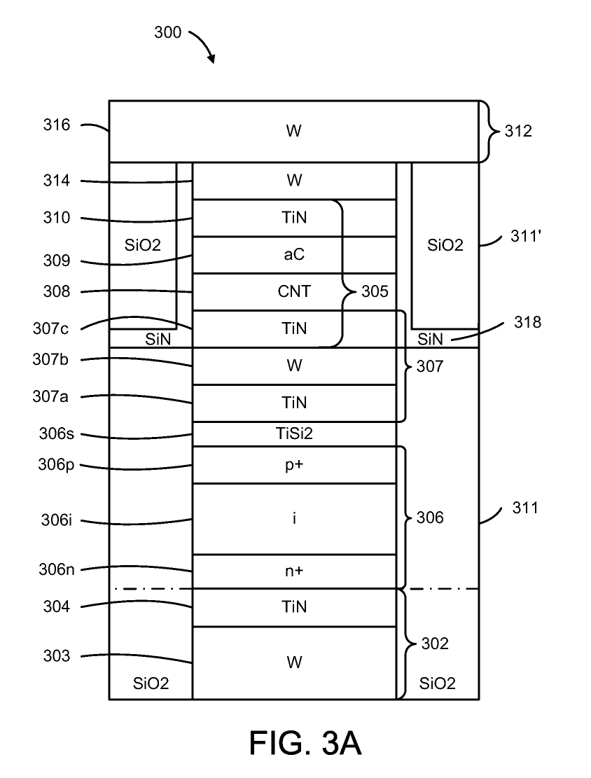

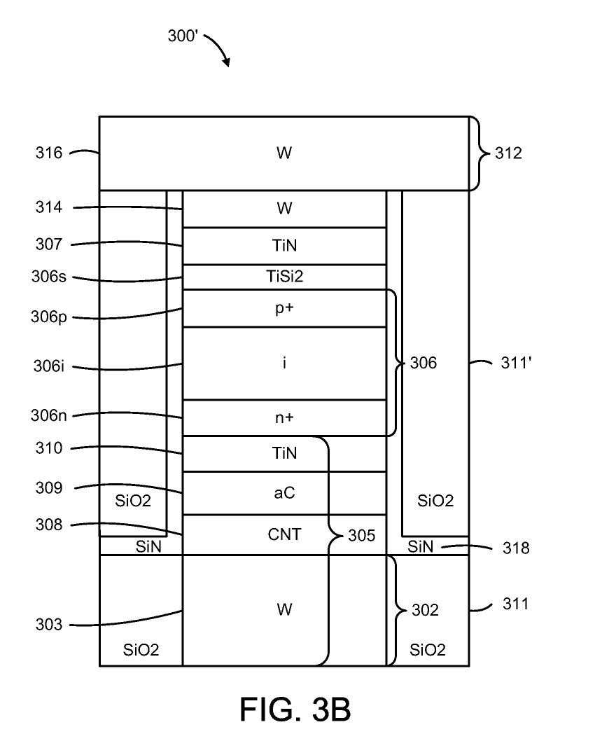

In some embodiments, a silicide region (not shown in FIG. 2; see FIG. 3) may be formed in contact with the diode 206, above or below it. As described in U.S. Pat. No. 7,176,064, “MEMORY CELL COMPRISING A SEMICONDUCTOR JUNCTION DIODE CRYSTALLIZED ADJACENT TO A SILICIDE,” which is hereby incorporated by reference herein in its entirety, silicide-forming materials such as titanium and cobalt react with deposited silicon during annealing to form a silicide layer. The lattice spacings of titanium silicide and cobalt silicide are close to that of silicon, and it appears that such silicide layers may serve as “crystallization templates” or “seeds” for adjacent deposited silicon as the deposited silicon crystallizes (e.g., the silicide layer enhances the crystalline structure of the diode 206 during annealing). Lower resistivity silicon thereby is provided. Similar results may be achieved for silicon-germanium alloy and/or germanium diodes.

A TiN, TaN, W, TaCN or other adhesion/barrier layer 207 may be formed above the diode 206. In some embodiments, a metal hard mask such as W or the like may be employed on top of the adhesion/barrier layer 207. The adhesion/barrier layer 207 and diode 206 may be patterned and etched to form a pillar. In general, a plurality of these pillars may be provided and isolated from one another, such as by employing SiO₂ or other dielectric material isolation between each of the pillars (e.g., by depositing dielectric material over the pillars and then planarizing the device structure to re-expose the electrically-isolated pillars).

As shown in FIG. 2A, adhesion layer 207 may function as a bottom electrode of MIM device 205 that includes CNT material 208 and optional carbon-based material 209 as the insulating layer, and an adhesion layer 210 as a top electrode. As such, the following sections refer to adhesion/barrier layer 207 as “bottom electrode 207” of MIM 205 with respect to FIG. 2A.

CNT material 208 may be formed over the bottom electrode 207 using any suitable CNT formation process (as described previously). In some embodiments in accordance with this invention, following deposition/formation of the CNT material 208, a second carbon-based material layer 209 may be formed as a protective liner covering the CNT material 208. The carbon-based liner may be formed as described above, such as described previously with reference to FIG. 1. In the embodiment shown in FIG. 2B, the diode 206 may be positioned above the CNT material 208 and carbon-based liner 209.

Following deposition/formation of the CNT material 208 and carbon-based liner 209, a second adhesion/barrier layer 210, such as TiN, TaN or the like, is formed over the carbon-based material 209. As described above, adhesion layer 210 may function as a top electrode of MIM 205. As such, the following sections refer to adhesion/barrier layer 210 as “top electrode 210” of MIM 205.

In some embodiments in accordance with this invention, top electrode 210 may be deposited using a lower energy deposition technique, such as chemical vapor deposition (“CVD”), atomic layer deposition (“ALD”), a combination of CVD and ALD techniques, and/or electron beam (“e-beam”) evaporation. The stack may be patterned, for example, with about 1 to about 1.5 microns, more preferably about 1.2 to about 1.4 microns, of photoresist using standard photolithographic techniques. The stack then is etched.

In some embodiments, the CNT material 208 and carbon-based liner 209 may be etched using a different etch step than the etch step used for the top electrode 210 (e.g., consecutively in the same chamber). For example, the top electrode 210 may be etched using a chlorine process (similar to that of Table 1, above, or Table 2, below, without the argon flow) while the CNT material 208 may be etched using a chlorine-argon chemistry (similar to that of Table 2). In other embodiments, a single etch step may be used (e.g., using a chlorine-argon chemistry as in Table 2). However, in some embodiments, it has been found that using argon during the carbon material etch increases the etch rate of the carbon material.

Etching carbon materials using chlorine and argon chemistries may be performed as described below, and such a method is compatible with standard semiconductor tooling. For example, a plasma etch tool may generate a plasma based on BCl₃, Cl₂ and argon gas flow inputs, generating reactive species such as Cl+ and Ar+ that may etch a CNT material. In some embodiments, a low bias power of about 100 Watts or less may be employed, although other power ranges may be used. Exemplary processing conditions for a CNT material, plasma etch process are provided below in Table 2. Other flow rates, chamber pressures, power levels, process temperatures, and/or etch rates may be used.

TABLE 2
EXEMPLARY PLASMA ETCH PROCESS PARAMETERS

| | EXEMPLARY | PREFERRED |
|---|---|---|
| PROCESS PARAMETER | RANGE | RANGE |
| BCl₃ Flow Rate (sccm) | 30-70 | 45-60 |
| Cl₂ Flow Rate (sccm) | 0-50 | 15-25 |
| Argon Flow Rate (sccm) | 0-50 | 15-25 |
| Pressure (milliTorr) | 50-150 | 80-100 |
| Substrate Bias RF (Watts) | 100-200 | 125-175 |
| Plasma RF (Watts) | 350-550 | 390-410 |
| Process Temperature (° C.) | 45-75 | 60-70 |
| Etch Rate (Å/sec) | 10-20 | 13.8-14.5 |

Such an etched film stack has been observed to have nearly vertical sidewalls and little or no undercut of the CNT material 208. The defined top electrode/aC/CNT features are then isolated with SiO₂ or other dielectric fill 211, planarized and a second conductor 212 is formed over the top electrode 210 and gap fill 211. The second conductor 212 may include a barrier/adhesion layer 214, such as TiN, TaN or a similar layer, and a metal layer 216, such as a W or other conductive layer.

In some embodiments, the etch stack may include about 1 to about 1.5 microns, more preferably about 1.2 to about 1.4 microns of photoresist, about 2250 to about 2750 angstroms of SiO₂ hardmask, about 1800 to about 2200 angstroms of TiN (per TiN layer), about 750 to about 950 angstroms of CNT material 208, and about 750 to about 950 angstroms of carbon-based material 209. Other material thicknesses may be used. The oxide hard mask may be etched using an oxide etcher and conventional chemistries using an endpoint to stop on the top electrode 210. The adhesion/barrier and CNT layers may be etched using a metal etcher, for example. An exemplary metal etcher is the LAM 9600 metal etcher, available from Lam of Fremont, Calif. Other etchers may be used.

In some embodiments, the photoresist (“PR”) may be ashed using standard procedures before continuing to the adhesion/barrier and CNT etch, while in other embodiments the PR is not ashed until after the CNT etch. In both cases, a 2000 angstrom TiN adhesion/barrier layer may be etched using about 85-110 Watts bias, about 45-60 standard cubic centimeters per minute (“sccm”) of BCl₃, and about 15-25 sccm of Cl₂ for about a 60 second timed etch. Other bias powers, flow rates and etch durations may be used. In embodiments in which the PR is ashed, the CNT etch may include about 45-60 sccm of BCl₃, about 15-25 sccm of Cl₂ and about 15-25 sccm of Argon using about 125-175 Watts bias for about 55-65 seconds. In embodiments in which the PR is not ashed, the identical conditions may be used with a longer etch time (e.g., about 60-70 seconds). In either case, a chuck temperature of 60-70° C. may be employed during the CNT etch. Exemplary ranges for the CNT dry etch include about 100 to 250 Watts bias, about 45 to 85° C. chuck temperature, and a gas ratio range of about 2:1 to 5:1 BCl₃:Cl₂ and about 5:1 Ar:Cl₂ to no argon. The etch time may be proportional to the CNT thickness.

A novel ash may be used for a post-etch clean when the PR is not ashed prior to etching. For example, the bias and/or directionality component of the ashing process may be increased and the pressure of oxygen during the ashing process may be reduced. Both attributes may help to reduce undercutting of the CNT material. Any suitable ashing tool may be used, such as an Iridia asher available from GaSonics International of San Jose, Calif.

In some embodiments, an ashing process may include two steps (e.g., when a third high pressure oxygen step is removed). Exemplary process conditions for the first ashing step are provided in Table 3 below. Exemplary process conditions for the second ashing step are provided in Table 4 below. Other flow rates, pressures, RF powers and/or times may be used.

TABLE 3
EXEMPLARY FIRST ASHING STEP PROCESS PARAMETERS

| | EXEMPLARY | PREFERRED |
|---|---|---|
| PROCESS PARAMETER | RANGE | RANGE |
| CF₄ Flow Rate (sccm) | 10-50 | 20-30 |
| N₂H₂ Flow Rate (sccm) | 80-120 | 90-110 |
| H₂O₂ Flow Rate (sccm) | 200-350 | 260-290 |
| Pressure (milliTorr) | 600-800 | 650-750 |
| Substrate Bias RF (Watts) | 0 | 0 |
| Plasma RF (Watts) | 350-450 | 400-430 |
| Time (seconds) | 20-120 | 50-70 |

TABLE 4
EXEMPLARY SECOND ASHING
STEP PROCESS PARAMETERS

| | EXEMPLARY | PREFERRED |
|---|---|---|
| PROCESS PARAMETER | RANGE | RANGE |
| O₂ Flow Rate (sccm) | 350-450 | 380-420 |
| Pressure (milliTorr) | 200-600 | 380-440 |
| Substrate Bias RF (Watts) | 50-200 | 90-120 |
| Plasma RF (Watts) | 350-450 | 400-430 |
| Time (seconds) | 20-120 | 50-70 |

The bias power may be increased from zero for normal processing. No ashing is used post CNT etch when PR ashing is performed prior to CNT etching. Ashing time is proportional to resist thickness used. Post CNT etch cleaning, whether or not PR ashing is performed before CNT etching, may be performed in any suitable cleaning tool, such as a Raider tool, available from Semitool of Kalispell, Mont. Exemplary post CNT etch cleaning may include using ultra-dilute sulfuric acid (e.g., about 1.5-1.8 wt %) for about 60 seconds and ultra-dilute HF (e.g., about 0.4-0.6 wt %) for 60 seconds. Megasonics may or may not be used.

In accordance with a third exemplary embodiment of this invention, formation of a microelectronic structure includes formation of a diode in series with an MIM device having CNT material, such as in FIG. 2. The third embodiment of the invention also includes a dielectric sidewall liner provided to protect the CNT material from degradation during a dielectric fill step. The dielectric liner and its use are compatible with standard semiconductor tooling.

FIG. 3 is a cross-sectional elevational view of an exemplary memory cell structure 300 provided in accordance with the present invention. FIG. 3 comprises FIGS. 3A and 3B, which depict layers of the memory cell formed in different orders. In FIG. 3A, memory cell structure 300 includes a diode disposed below an MIM device having a CNT film covered by a carbon-based protective layer and disposed between a bottom electrode and a top electrode. In FIG. 3B, memory cell structure 300′ has the diode disposed above the MIM device.

As shown in FIG. 3A, the memory cell structure 300 includes a first conductor 302 formed over a substrate (not shown). The first conductor 302 may include a first metal layer 303, such as a W, Cu, Al, Au, or other metal layer, with a first barrier/adhesion layer 304, such as a TiN, TaN or similar layer, formed over the first metal layer 303. As shown in FIG. 3B, the first conductor 204 may comprise a lower portion of a MIM structure 305 and function as a bottom electrode of MIM 305. In general, a plurality of the first conductors 302 may be provided and isolated from one another (e.g., by employing SiO₂ or other dielectric material isolation between each of the first conductors 302).

A vertical P-I-N (or N-I-P) diode 306 is formed above first conductor 302. For example, the diode 306 may include a polycrystalline (e.g., polysilicon, polygermanium, silicon-germanium alloy, etc.) diode. Diode 306 may include a layer 306n of semiconductor material heavily doped a dopant of a first-type, e.g., n-type; a layer 306i of intrinsic or lightly doped semiconductor material; and a layer 306p of semiconductor material heavily doped a dopant of a second-type, e.g., p-type. Alternatively, the vertical order of the diode 306 layers 306n, 306i, and 306p may be reversed, analogous to the diode 206 shown in FIG. 2B.

In some embodiments, an optional silicide region 306s may be formed over the diode 306. As described in U.S. Pat. No. 7,176,064, which is hereby incorporated by reference herein in its entirety for all purposes, silicide-forming materials such as titanium and cobalt react with deposited silicon during annealing to form a silicide layer. The lattice spacings of titanium silicide and cobalt silicide are close to that of silicon, and it appears that such silicide layers may serve as “crystallization templates” or “seeds” for adjacent deposited silicon as the deposited silicon crystallizes (e.g., the silicide layer enhances the crystalline structure of the diode 306 during annealing). Lower resistivity silicon thereby is provided. Similar results may be achieved for silicon-germanium alloy and/or germanium diodes. In some embodiments using silicide region 306s to crystallize the diode 306, the silicide region 306s may be removed after such crystallization, so that the silicon region 306s does not remain in the finished structure.

A TiN or other adhesion/barrier layer or layer stack 307 may be formed above the diode 306. In some embodiments, adhesion/barrier layer 307 may comprise a layer stack 307 including a first adhesion/barrier layer 307a, a metal layer 307b, such as of W, and a further adhesion/barrier layer 307c, such as of TiN.

In the event that a layer stack 307 is used, layers 307a and 307b may serve as a metal hard mask that may act as a chemical mechanical planarization (“CMP”) stop layer and/or etch-stop layer. Such techniques are disclosed, for example, in U.S. patent application Ser. No. 11/444,936, “CONDUCTIVE HARD MASK TO PROTECT PATTERNED FEATURES DURING TRENCH ETCH,” filed May 31, 2006, which is hereby incorporated by reference herein in its entirety. For instance, the diode 306 and layers 307a and 307b may be patterned and etched to form pillars, and dielectric fill material 311 may be formed between the pillars. The stack may then be planarized, such as by CMP or etch-back, to co-expose the gap fill 311 and layer 307b. Layer 307c may then be formed on layer 307b. Alternatively, layer 307c may be patterned and etched along with diode 306 and layers 307a and 307b. In some embodiments, the layer 307c may be eliminated, and the CNT material may interface directly with the layer 307b (e.g., W).

Thereafter, a CNT material 308 may be formed over the adhesion/barrier layer or layer stack 307 using any suitable CNT formation process (as described previously). Following deposition/formation of the CNT material 308, a second carbon-based material layer 309 may be formed as a protective liner covering the CNT material 308. The carbon-based liner 309 may be formed as described above. Following deposition/formation of the carbon-based liner 309, a second adhesion/barrier layer 310, such as TiN, TaN or the like, is formed over the carbon-based liner material 309.

As shown in FIG. 3A, adhesion layer 307 may function as a bottom electrode of MIM device 305 that includes CNT material 308 and optional carbon-based material 309 as the insulating layer, and an adhesion layer 310 as a top electrode. As such, the following sections refer to adhesion/barrier layer 307 as “bottom electrode 307” with respect to FIG. 3A. Similarly, adhesion/barrier layer 310 is referred to as “top electrode 310” of the MIM 305 of FIG. 3A as well as FIG. 3B.

Top electrode 310 may be deposited using a lower energy deposition technique, such as chemical vapor deposition (“CVD”), atomic layer deposition (“ALD”), a combination of CVD and ALD, and/or electron beam (“e-beam”) evaporation. An additional hardmask and/or CMP stop layer 314 also may be formed (as shown).

Before formation of a top conductor 312, which may include an adhesion layer (not shown) and a conductive layer 316, the stack may be patterned, for example, with about 1 to about 1.5 micron, more preferably about 1.2 to about 1.4 micron, photoresist using standard photolithographic techniques. The stack then is etched. If an etching process was performed to create the pillars mentioned above, then the etch may apply to layers 308, 309, 310, and possibly 307c and 314. For example, the layers 314, 310 may serve as a hardmask and/or CMP stop for the CNT material 308 and carbon-based liner 309.

In some embodiments, the CNT material 308 and carbon-based liner 309 may be etched using a different etch step than the etch step used for the second adhesion/barrier layer 310 (e.g., consecutively in the same chamber). For example, the stack may be etched using a plasma etcher and using a chlorine chemistry followed by a chlorine-argon chemistry under low bias conditions (e.g., a chlorine chemistry may be used to etch the TiN film and a chlorine-argon chemistry may be used to etch the CNT material), as described previously with reference to the second embodiment. In other embodiments, a single etch step may be used (e.g., using a chlorine chemistry, such as in Table 1, or a chlorine-argon chemistry, such as in Table 2, for both the TiN and CNT materials). Such an etched film stack has been observed to have nearly vertical sidewalls and little or no undercut of the CNT material 308. In some embodiments, the CNT material 308 may be overetched such that etching of underlying dielectric gap fill material may occur.

After the etch of the TiN and CNT layers, the stack may be cleaned prior to dielectric gap fill. After cleaning, deposition of gap fill 311′ may occur. Standard PECVD techniques for depositing dielectric material may employ an oxygen plasma component that is created in the initial stages of deposition. This initial oxygen plasma may harm the CNT material 308, causing undercutting and poor electrical performance. To avoid this oxygen plasma exposure, a pre-dielectric fill liner 318 may be formed with a different deposition chemistry (e.g., without a high oxygen component) to protect the CNT material 308 and carbon-based liner 309 as the remaining gap-fill dielectric 311′ (e.g., SiO₂) is deposited. In one exemplary embodiment, a silicon nitride pre-dielectric fill liner 318 followed by a standard PECVD SiO₂ dielectric fill 311′ may be used. Stoichiometric silicon nitride is Si₃N₄, but “SiN” is used herein to refer to stoichiometric and non-stoichiometric silicon nitride alike.

In the embodiment of FIG. 3, a pre-dielectric fill liner 318 is deposited conformally over the top electrode/aC/CNT features (or top electrode/aC/CNT/TiN features) before gap fill portion 311′, e.g., the remainder of the dielectric gap fill, is deposited. The fill liner 318 preferably covers the outer sidewalls of the CNT material 308 and carbon-based liner 309 and isolates them from the dielectric fill 311′. In some embodiments, the fill liner 318 may comprise about 200 to about 500 angstroms of SiN. However, the structure optionally may comprise other layer thicknesses and/or other materials, such as SiₓC_{y}N_{z} and SiₓN_{y}O_{z} (with low O content), etc., where x, y and z are non-zero numbers resulting in stable compounds. In embodiments in which the CNT material 308 is overetched such that etching of underlying dielectric gap fill material occurs, the fill liner 318 may extend below the CNT material 108.

The defined top electrode/aC/CNT (or top electrode/aC/CNT/TiN) features are then isolated, with SiO₂ or other dielectric fill 311′, and planarized, to co-expose the top electrode 310 and gap fill 311′. A second conductor 312 is formed over the second adhesion/barrier layer 310, or layer 314, if layer 314 is used as a hard mask and etched along with layers 308, 309, and 310. The second conductor 312 may include a barrier/adhesion layer, such as TiN, TaN or a similar layer, as shown in FIGS. 1 and 2, and a metal layer 316, such as a W or other conductive layer. In contrast to FIGS. 1 and 2, FIG. 3 depicts a layer 314 of tungsten deposited on adhesion/barrier layer 310 before the stack is etched, so that layer 314 is etched as well. Layer 314 may act as a metal hard mask to assist in etching the layers beneath it. Insofar as layers 314 and 316 both may be tungsten, they should adhere to each other well. Optionally, a SiO₂ hard mask may be used.

In one exemplary embodiment, a SiN pre-dielectric fill liner may be formed using the process parameters listed in Table 5. Other powers, temperatures, pressures, thicknesses and/or flow rates may be used.

TABLE 5
SiN PRE-DIELECTRIC FILL LINER PROCESS PARAMETERS

| | EXEMPLARY | PREFERRED |
|---|---|---|
| PROCESS PARAMETER | RANGE | RANGE |
| SiH₄ Flow Rate (sccm) | 0.1-2.0 | 0.4-0.7 |
| NH₃ Flow Rate (sccm) | 2-10 | 3-5 |
| N₂ Flow Rate (sccm) | 0.3-4 | 1.2-1.8 |
| Temperature (° C.) | 300-500 | 350-450 |
| Low Frequency Bias (Kilowatts) | 0-1 | 0.4-0.6 |
| High Frequency Bias (Kilowatts) | 0-1 | 0.4-0.6 |
| Thickness (Angstroms) | 200-500 | 280-330 |

Liner film thickness scales linearly with time. Preferably after the pre-dielectric fill liner 318 is deposited, the remaining thicker dielectric fill 311′ may be immediately deposited (e.g., in the same tool). Exemplary SiO₂ dielectric fill conditions are listed in Table 6. Other powers, temperatures, pressures, thicknesses and/or flow rates may be used.

TABLE 6
EXEMPLARY Si0₂ DIELECTRIC
FILL PROCESS PARAMETERS

| | EXEMPLARY | PREFERRED |
|---|---|---|
| PROCESS PARAMETER | RANGE | RANGE |
| SiH₄ Flow Rate (sccm) | 0.1-2.0 | 0.2-0.4 |
| N₂O Flow Rate (sccm) | 5-15 | 9-10 |
| N₂ Flow Rate (sccm) | 0-5 | 1-2 |
| Temperature (° C.) | 300-500 | 350-450 |
| Low Frequency Bias (Kilowatts) | 0 | 0 |
| High Frequency Bias (Kilowatts) | 0.5-1.8 | 1-1.2 |
| Thickness (Angstroms) | 50-5000 | 2000-3000 |

Gap fill film thickness scales linearly with time. The SiO₂ dielectric fill 311′ can be any thickness, and standard SiO₂ PECVD methods may be used.

Using a thinner SiN liner 318 gives a continuous film and adequate protection to the oxygen plasma from a PECVD SiO₂ deposition without the stress associated with thicker SiN films. Additionally, standard oxide chemistry and slurry advantageously may be used to chemically mechanically polish away a thin SiN liner 318 before forming conductor 312, without having to change to a SiN specific CMP slurry and pad part way through the polish.

In some embodiments, use of a pre-dielectric fill liner provided the highest yield of devices with forward currents in the range from about 10⁻⁵ to about 10⁻⁴ amperes. Additionally, use of a SiN liner provided individual devices with the largest cycles of operation. Moreover, data indicate that using thin SiN as a protective barrier against CNT material degradation during a dielectric fill improves electrical performance.

As shown in FIG. 3B, microelectronic structure 300′ may include the diode 306 positioned above the CNT material 308 and carbon-based liner 309, causing some rearrangement of the other layers. In particular, CNT material 308 may be deposited either on an adhesion/barrier layer 304, as shown in FIG. 3A, or directly on the lower conductor 302, as shown in FIG. 3B. Tungsten from a lower conductor may assist catalytically in formation of CNT material 308. The carbon-based liner 309 then may be formed on the CNT material 308. An adhesion/barrier layer 310 may be formed on the carbon-based liner 309, followed by formation of diode 306, including possible silicide region 306s. An adhesion/barrier layer 307 may be formed on the diode 306 (with or without silicide region 306s).

FIG. 3B depicts a layer 314, such as tungsten, on layer 307, and layer 314 may serve as a metal hard mask and/or adhesion layer to the metal layer 316 of the second conductor 312, preferably also made of tungsten. The stack may be patterned and etched into a pillar, as described above, and a pre-dielectric fill liner 318 may be deposited conformally on the pillar and the dielectric fill 311 that isolates the first conductors 302. In this case, the liner 318 may extend upward the entire height of the stack between the first and second conductors 302 and 312.

In accordance with a fourth exemplary embodiment of this invention, formation of a microelectronic structure includes formation of a monolithic three dimensional memory array including memory cells comprising an MIM device having a carbon-based memory element disposed between a bottom electrode and a top electrode. The carbon-based memory element may comprise an optional carbon-based protective layer covering undamaged, or reduced-damage, CNT material that is not penetrated, and preferably not infiltrated, by the top electrode. The top electrode in the MIM may be deposited using a lower energy deposition technique, such as chemical vapor deposition (“CVD”), atomic layer deposition (“ALD”), a combination of CVD and ALD, and/or electron beam (“e-beam”) evaporation.

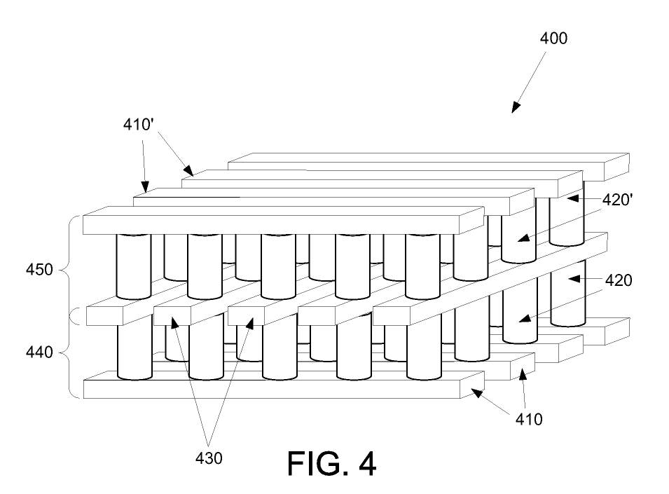

FIG. 4 shows a portion of a memory array 400 of exemplary memory cells formed according to the fourth exemplary embodiment of the present invention. Memory array 400 may include first conductors 410, 410′ that may serve as wordlines or bitlines, respectively; pillars 420, 420′ (each pillar 420, 420′ comprising a memory cell); and second conductors 430, that may serve as bitlines or wordlines, respectively. First conductors 410, 410′ are depicted as substantially perpendicular to second conductors 430. Memory array 400 may include one or more memory levels. A first memory level 440 may include the combination of first conductors 410, pillars 420 and second conductors 430, whereas a second memory level 450 may include second conductors 430, pillars 420′ and first conductors 410′. Fabrication of such a memory level is described in detail in the applications incorporated by reference herein.

Embodiments of the present invention prove particularly useful in formation of a monolithic three dimensional memory array. A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167. The substrates may be thinned or removed from the memory levels before bonding, but as the memory levels are initially formed over separate substrates, such memories are not true monolithic three dimensional memory arrays.

A related memory is described in Herner et al., U.S. patent application Ser. No. 10/955,549, “NONVOLATILE MEMORY CELL WITHOUT A DIELECTRIC ANTIFUSE HAVING HIGH- AND LOW-IMPEDANCE STATES,” filed Sep. 29, 2004 (hereinafter the '549 application), which is hereby incorporated by reference herein in its entirety. The '549 application describes a monolithic three dimensional memory array including vertically oriented p-i-n diodes like diode 206 of FIG. 2. As formed, the polysilicon of the p-i-n diode of the '549 application is in a high-resistance state. Application of a programming voltage permanently changes the nature of the polysilicon, rendering it low-resistance. It is believed the change is caused by an increase in the degree of order in the polysilicon, as described more fully in Herner et al., U.S. patent application Ser. No. 11/148,530, “NONVOLATILE MEMORY CELL OPERATING BY INCREASING ORDER IN POLYCRYSTALLINE SEMICONDUCTOR MATERIAL,” filed Jun. 8, 2005 (the “'530 application”), which is incorporated by reference herein in its entirety. This change in resistance is stable and readily detectable, and thus can record a data state, allowing the device to operate as a memory cell. A first memory level is formed above the substrate, and additional memory levels may be formed above it. These memories may benefit from use of the methods and structures according to embodiments of the present invention.

Another related memory is described in Herner et al., U.S. Pat. No. 7,285,464, (the “'464 patent”), which is incorporated by reference herein in its entirety. As described in the '464 patent, it may be advantageous to reduce the height of the p-i-n diode. A shorter diode requires a lower programming voltage and decreases the aspect ratio of the gaps between adjacent diodes. Very high-aspect ratio gaps are difficult to fill without voids. A thickness of at least 600 angstroms is preferred for the intrinsic region to reduce current leakage in reverse bias of the diode. Forming a diode having a silicon-poor intrinsic layer above a heavily n-doped layer, the two separated by a thin intrinsic capping layer of silicon-germanium, will allow for sharper transitions in the dopant profile, and thus reduce overall diode height.

In particular, detailed information regarding fabrication of a similar memory level is provided in the '549 application and the '464 patent, previously incorporated. More information on fabrication of related memories is provided in Herner et al., U.S. Pat. No. 6,952,030, “A HIGH-DENSITY THREE-DIMENSIONAL MEMORY CELL,” owned by the assignee of the present invention and hereby incorporated by reference herein in its entirety for all purposes. To avoid obscuring the present invention, this detail will be not be reiterated in this description, but no teaching of these or other incorporated patents or applications is intended to be excluded. It will be understood that the above examples are non-limiting, and that the details provided herein can be modified, omitted, or augmented while the results fall within the scope of the invention.

The foregoing description discloses exemplary embodiments of the invention. Modifications of the above disclosed apparatus and methods that fall within the scope of the invention will be readily apparent to those of ordinary skill in the art. Accordingly, although the present invention has been disclosed in connection with exemplary embodiments, it should be understood that other embodiments may fall within the spirit and scope of the invention, as defined by the following claims.

1. A method of forming a microelectronic structure, the method comprising:
forming a layer of carbon-based material above a bottom electrode; and
using a lower energy deposition technique to form a top electrode above and in contact with the layer of carbon-based material.

2. The method of claim 1, wherein:
the layer of carbon-based material comprises a carbon-based memory element.

3. The method of claim 1, wherein:
the carbon-based material comprises carbon nanotubes.

4. The method of claim 1, wherein:
using the lower energy deposition technique to form the top electrode exposes the layer of carbon-based material to a first energy level, and the first energy level is insufficient to render the layer of carbon-based material non-functional.

5. The method of claim 1, wherein:
using the lower energy deposition technique to form the top electrode exposes the layer of carbon-based material to a first energy level, and the first energy level is insufficient to cause the top electrode to penetrate the layer of carbon-based material.

6. The method of claim 1, wherein:
using the lower energy deposition technique to form the top electrode exposes the layer of carbon-based material to a first energy level lower than a second energy level to which the layer of carbon-based material would be exposed if physical vapor deposition were used to form the top electrode.

7. The method of claim 1, wherein:
the lower energy deposition technique comprises CVD, PECVD, thermal CVD, ALD, PE-ALD, high-throughput ALD, a hybridization of ALD and CVD, or e-beam evaporation.

8. The method of claim 1, wherein the layer of carbon-based material comprises a carbon-based active layer.

9. The method of claim 1, further comprising:
etching the layer of carbon-based material and the top electrode to form a pillar;
forming a conformal pre-dielectric-fill liner around the pillar; and
forming a dielectric fill layer around the pre-dielectric-fill liner.

10. The method of claim 1, wherein:
the bottom electrode, the layer of carbon-based material, and the top electrode comprise an MIM,
the method further comprising:
forming a steering element in contact with the MIM.

11. A microelectronic structure comprising:
a bottom electrode;
a layer of carbon-based material disposed above and in contact with a bottom electrode; and
a top electrode above and in contact with the carbon-based liner;
wherein the top electrode comprises lower energy deposition-formed material.

12. The microelectronic structure of claim 11, wherein:
the layer of carbon-based material comprises a carbon-based memory element.

13. The microelectronic structure of claim 11, wherein:
the carbon-based material comprises carbon nanotubes.

14. The microelectronic structure of claim 11, wherein:
the layer of carbon-based material comprises undamaged or reduced-damage material.

15. The microelectronic structure of claim 11, wherein:
the top electrode does not penetrate through the layer of carbon-based material.

16. The microelectronic structure of claim 11, wherein:
the top electrode does not infiltrate into the layer of carbon-based material.

17. The microelectronic structure of claim 11, wherein:
the lower energy deposition-formed material comprises a sharp profile interface as a result of having been formed using CVD, PECVD, thermal CVD, ALD, PE-ALD, high-throughput ALD, a hybridization of ALD and CVD, or e-beam evaporation.

18. The microelectronic structure of claim 11, wherein the layer of carbon-based material comprises a carbon-based active layer.

19. The microelectronic structure of claim 11, wherein:
the layer of carbon-based material and the top electrode comprise a pillar,
the microelectronic structure further comprising:
a pre-dielectric-fill liner around the pillar; and
a dielectric fill layer around the pre-dielectric-fill liner.

20. The microelectronic structure of claim 11, wherein:
the bottom electrode, the layer of carbon-based material, and the top electrode comprise an MIM,
the microelectronic structure further comprising:
a steering element disposed in contact with the MIM.
